(19) United States
(12) Patent Application Publication
(10) Pub. No.: US 2026/0271512 A1
(43) Pub. Date: Sep. 10, 2026

(54) ORGANIC LIGHT-EMITTING DEVICE AND DISPLAY APPARATUS

(71) Applicant: BOE Technology Group Co., Ltd., Beijing (CN)

(72) Inventors: Lei CHEN, Beijing (CN); Xueqin CHEN, Beijing (CN)

(73) Assignee: BOE Technology Group Co., Ltd., Beijing (CN)

(21) Appl. No.: 18/881,760

(22) PCT Filed: Feb. 8, 2024
(86) PCT No.: PCT/CN2024/076859

§ 371 Date: Jan. 7, 2025

(30) Foreign Application Priority Data
Mar. 27, 2023 (CN) 202310308282.0

(51) Int. Cl. H10K 50/844; H10K 50/858

(52) U.S. Cl. CPC H10K 50/844; H10K 50/858

(57) ABSTRACT

An organic light-emitting device and a display apparatus, which belong to the technical field of display. The organic light-emitting device comprises a first electrode layer, a light-emitting functional layer, a second electrode layer and a capping layer, which are stacked in sequence, wherein the capping layer comprises a first capping layer material and a second capping layer material; at the same wavelength, the refractive index of the first capping layer material is greater than that of the second capping layer material; and the maximum absorption peak of the first capping layer material is located between a 360 nm waveband and a 400 nm waveband.

### CROSS-REFERENCE TO RELATED APPLICATIONS

The present disclosure is a U.S. National Stage Application of International Application No. PCT/CN2024/076859, filed on Feb. 8, 2024, which is based upon and claims priority to Chinese patent application No. 202310308282.0, filed Mar. 27, 2023, entitled “Organic Light-emitting device and display apparatus”, the entire contents of each are incorporated herein by reference.

### TECHNICAL FIELD

The present disclosure relates to the field of display technology, and in particular to an organic light-emitting device and a display apparatus.

### BACKGROUND

Organic light-emitting diode (OLED) devices currently used mostly use top-emitting device structures, using reflective anode and transparent cathode to enhance light extraction efficiency through microcavity effect. In this device, a very important functional layer is a capping layer. The capping layer includes two layers, the first layer is a high refractive index material, and the second layer is a low refractive index material. The capping layer achieves better light extraction effect through the combination of high and low refractive index.

In the prior art, high refractive index materials are usually used in combination with LIF. However, the device made in this way has a low lifetime.

The above information disclosed in the background art part is only used to enhance understanding of the background of the present disclosure, and therefore it may include information that does not constitute the prior art known to those of ordinary skill in the art.

### SUMMARY OF THE INVENTION

The purpose of the present disclosure is to provide an organic light-emitting device and a display apparatus to improve the life of the device.

In order to achieve the above-mentioned invention object, the present disclosure adopts the following technical solutions:

According to a first aspect of the present disclosure, an organic light-emitting device is provided, including a first electrode layer, a light-emitting functional layer, a second electrode layer and a capping layer sequentially stacked, wherein the capping layer includes a first capping layer material and a second capping layer material;
wherein, at the same wavelength, the refractive index of the first capping layer material is greater than the refractive index of the second capping layer material;
the maximum absorption peak position of the first capping layer material is located between 360 nm and 400 nm.

In an exemplary embodiment of the present disclosure, the second capping layer material is an organic material, and the maximum absorption peak position of the second capping layer material is located between 300 nm and 320 nm.

In an exemplary embodiment of the present disclosure, the absorption intensity of the first capping layer material at a wavelength of 400 nm is more than 70% of the intensity at the wavelength of the maximum absorption peak position.

In an exemplary embodiment of the present disclosure, the absorption intensity of the first capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position;
the absorption intensity of the second capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position.

In an exemplary embodiment of the present disclosure, the first capping layer material is selected from a monoaromatic amine or a diaromatic amine structure, and the structural formula of the first capping layer material contains at least one fused 180° plane conjugated structure.

In an exemplary embodiment of the present disclosure, the fused 180° plane conjugated structure is selected from the group consisting of the following structures:

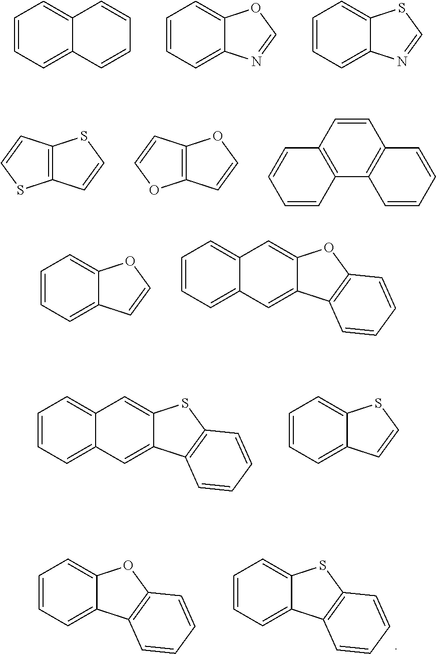

In an exemplary embodiment of the present disclosure, the structure of the first capping layer material is as shown in Chemical Formula 1 or Chemical Formula 2:

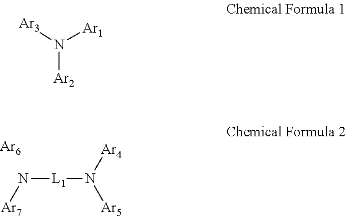

wherein, Ar₁, Ar₂, Ar₃, Ar₄, Ar₅, Ar₆, Ar₇ are each independently selected from substituted or unsubstituted aryl with 6-25 carbon atoms, substituted or unsubstituted heteroaryl with 5-25 carbon atoms, at least one of Ar₁, Ar₂, Ar₃ contains at least one fused 180° plane conjugated structure, and at least one of Ar₄, Ar₅, Ar₆, Ar₇ contains at least one fused 180° plane conjugated structure;
L₁ is selected from substituted or unsubstituted phenylene, substituted or unsubstituted biphenylene, substituted or unsubstituted naphthylene, substituted or unsubstituted fluorenylene, or a group formed by connecting any two of the above groups by a single bond;
the substituents on Ar₁, Ar₂, Ar₃, Ar₄, Ar₅, Ar₆, and Ar₇ are the same or different and are independently selected from aryl with 6 to 15 carbon atoms and heteroaryl with 5 to 15 carbon atoms;
the substituent on L₁ is selected from alkyl with 1 to 6 carbon atoms.

In an exemplary embodiment of the present disclosure, the fused 180° plane conjugated structure is selected from the group consisting of the following structures:

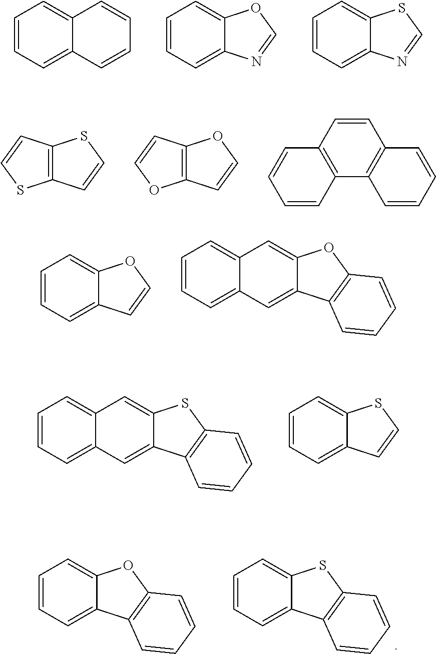

In an exemplary embodiment of the present disclosure, Ar₁, Ar₂, Ar₃, Ar₄, Ar₅, Ar₆, Ar₇ are each independently selected from the group consisting of the following groups:

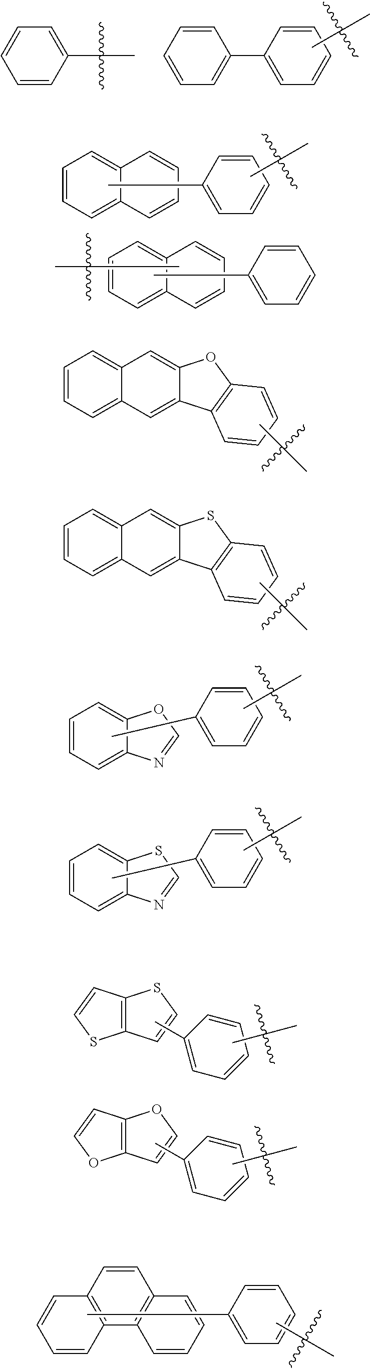

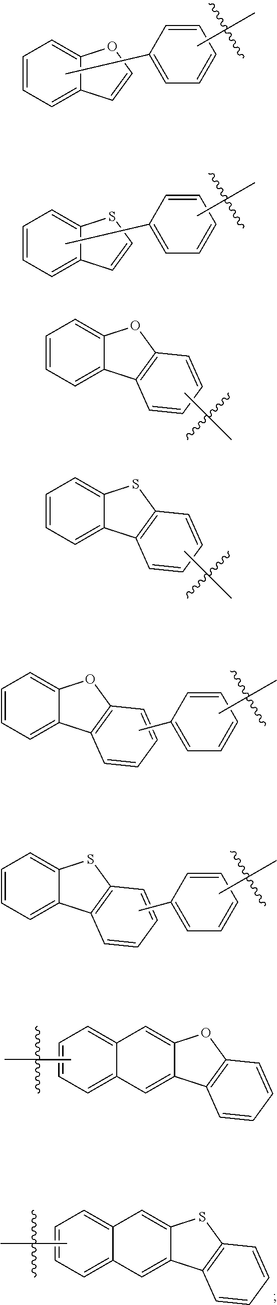

wherein,

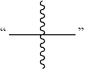

represents a chemical bond.

In an exemplary embodiment of the present disclosure, the structure of the second capping layer material does not include a fused 180° plane conjugated structure;
the second capping layer material has a structure containing at least three R groups, and the R group is substituted or unsubstituted alkyl with 1 to 6 carbon atoms or silane group;
the substituents on the substituted alkyl or silane groups are the same as or different from each other and are independently selected from fluorine or an alkyl with 1 to 4 carbon atoms.

In an exemplary embodiment of the present disclosure, the structure of the second capping layer material does not include a fused 180° plane conjugated structure;
the structure of the second capping layer material includes a non-conjugated structure, and the non-conjugated structure is selected from the group consisting of the following structures:

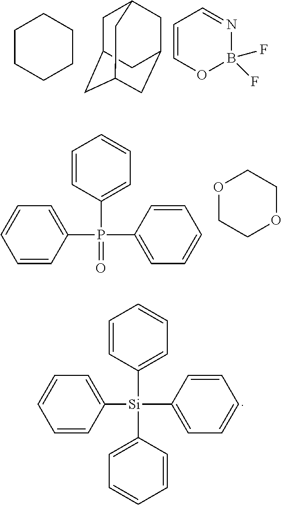

In an exemplary embodiment of the present disclosure, the structure of the second capping layer material includes at least three R groups, and the R groups are selected from methyl, tert-butyl, trimethylsilyl, and fluoromethyl.

In an exemplary embodiment of the present disclosure, the capping layer includes a first capping layer and a second capping layer stacked in a direction away from the first electrode layer, the first capping layer includes the first capping layer material, and the second capping layer includes the second capping layer material.

In an exemplary embodiment of the present disclosure, the refractive index of the first capping layer material at a wavelength of 450 nm to 650 nm is not less than 1.9, and the refractive index of the second capping layer material at a wavelength of 450 nm to 650 nm is not greater than 1.7.

In an exemplary embodiment of the present disclosure, the first capping layer material is selected from the following structural composition group:

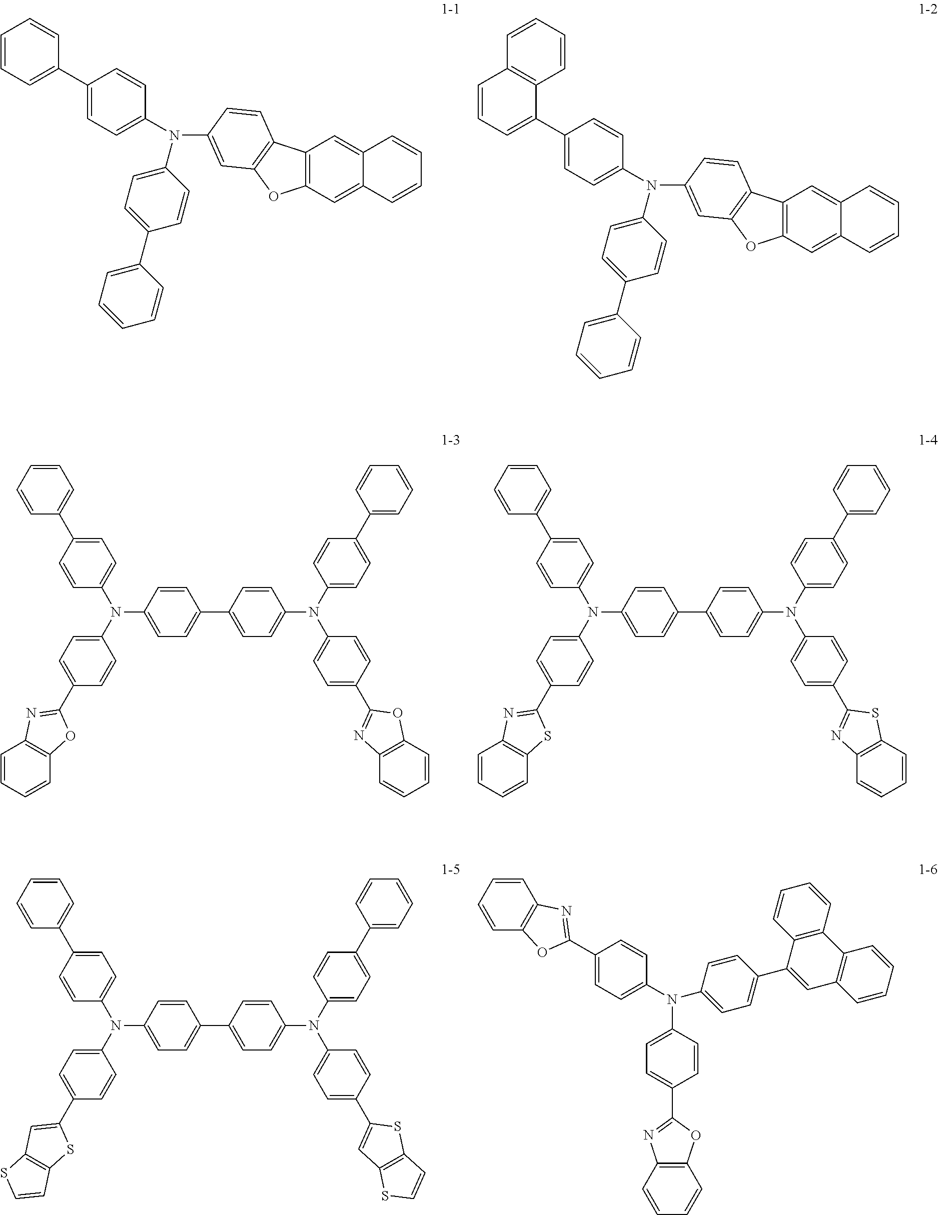

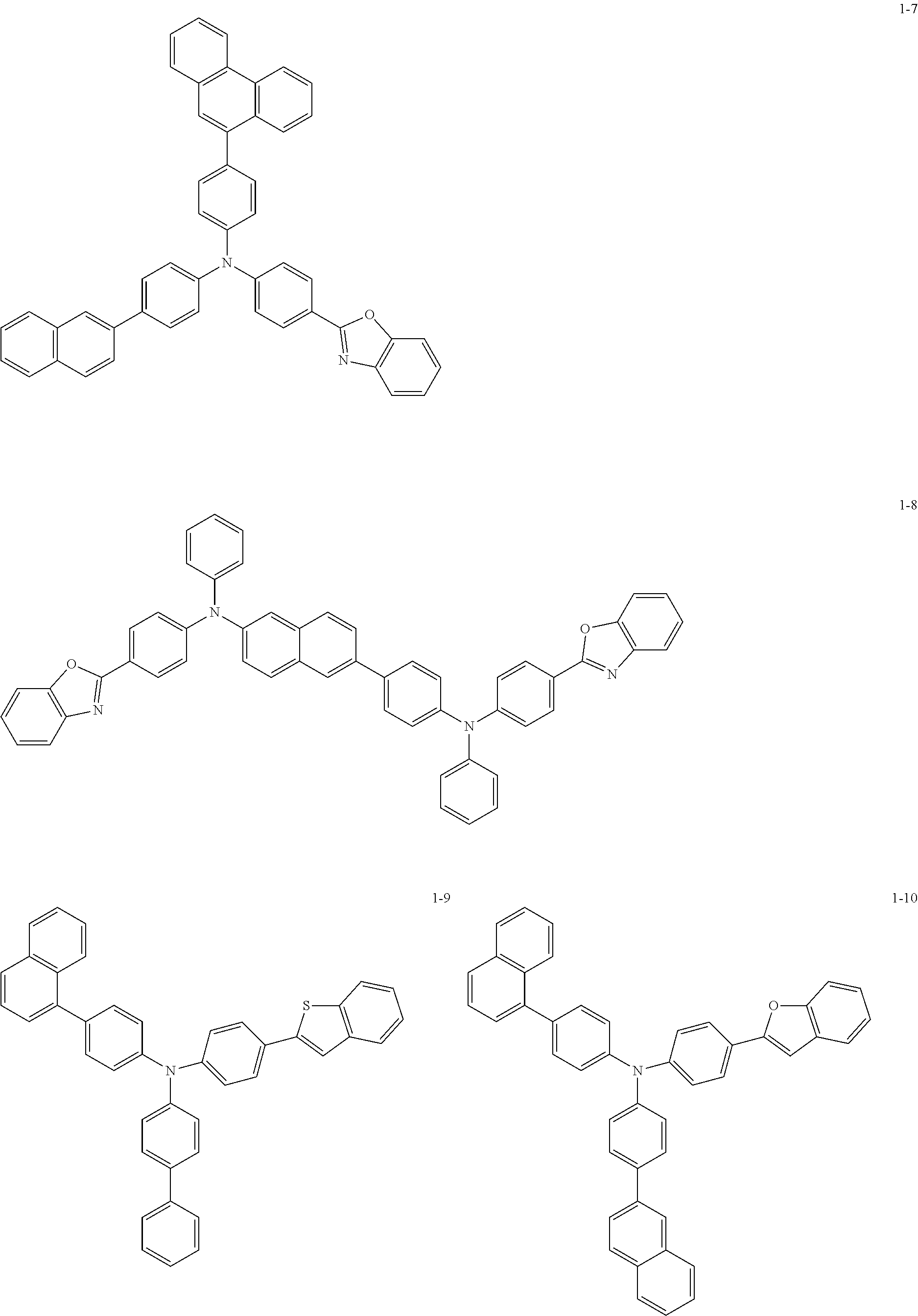 [SMILES: c1ccc2cc(-c3ccc(N(c4ccc(-c5nc6ccccc6o5)cc4)c4ccc(-c5cc6ccccc6c6ccccc56)cc4)cc3)ccc2c1 ; c1ccc(N(c2ccc(-c3ccc4cc(N(c5ccccc5)c5ccc(-c6nc7ccccc7o6)cc5)ccc4c3)cc2)c2ccc(-c3nc4ccccc4o3)cc2)cc1 ; c1ccc(-c2ccc(N(c3ccc(-c4cc5ccccc5s4)cc3)c3ccc(-c4cccc5ccccc45)cc3)cc2)cc1 ; c1ccc2cc(-c3ccc(N(c4ccc(-c5cc6ccccc6o5)cc4)c4ccc(-c5cccc6ccccc56)cc4)cc3)ccc2c1]

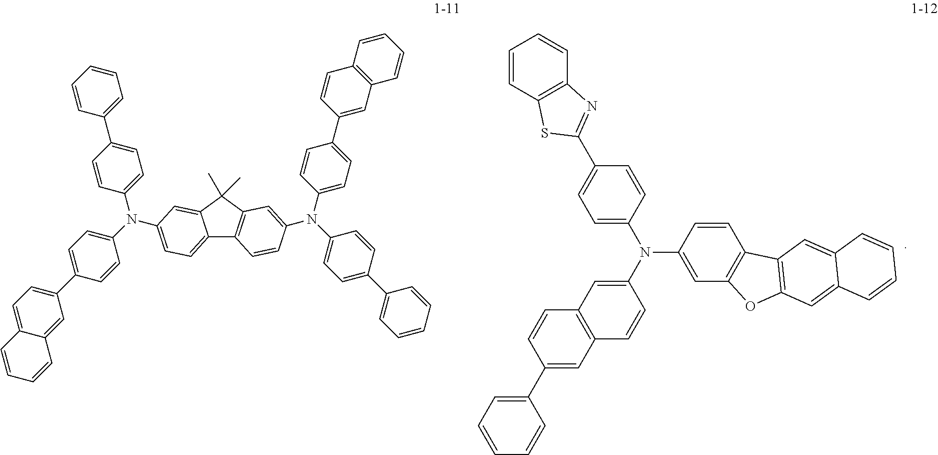 [SMILES: CC1(C)c2cc(N(c3ccc(-c4ccccc4)cc3)c3ccc(-c4ccc5ccccc5c4)cc3)ccc2-c2ccc(N(c3ccc(-c4ccccc4)cc3)c3ccc(-c4ccc5ccccc5c4)cc3)cc21 ; c1ccc(-c2ccc3cc(N(c4ccc(-c5nc6ccccc6s5)cc4)c4ccc5c(c4)oc4cc6ccccc6cc45)ccc3c2)cc1]

In an exemplary embodiment of the present disclosure, the second capping layer material is selected from the group consisting of the following structures:

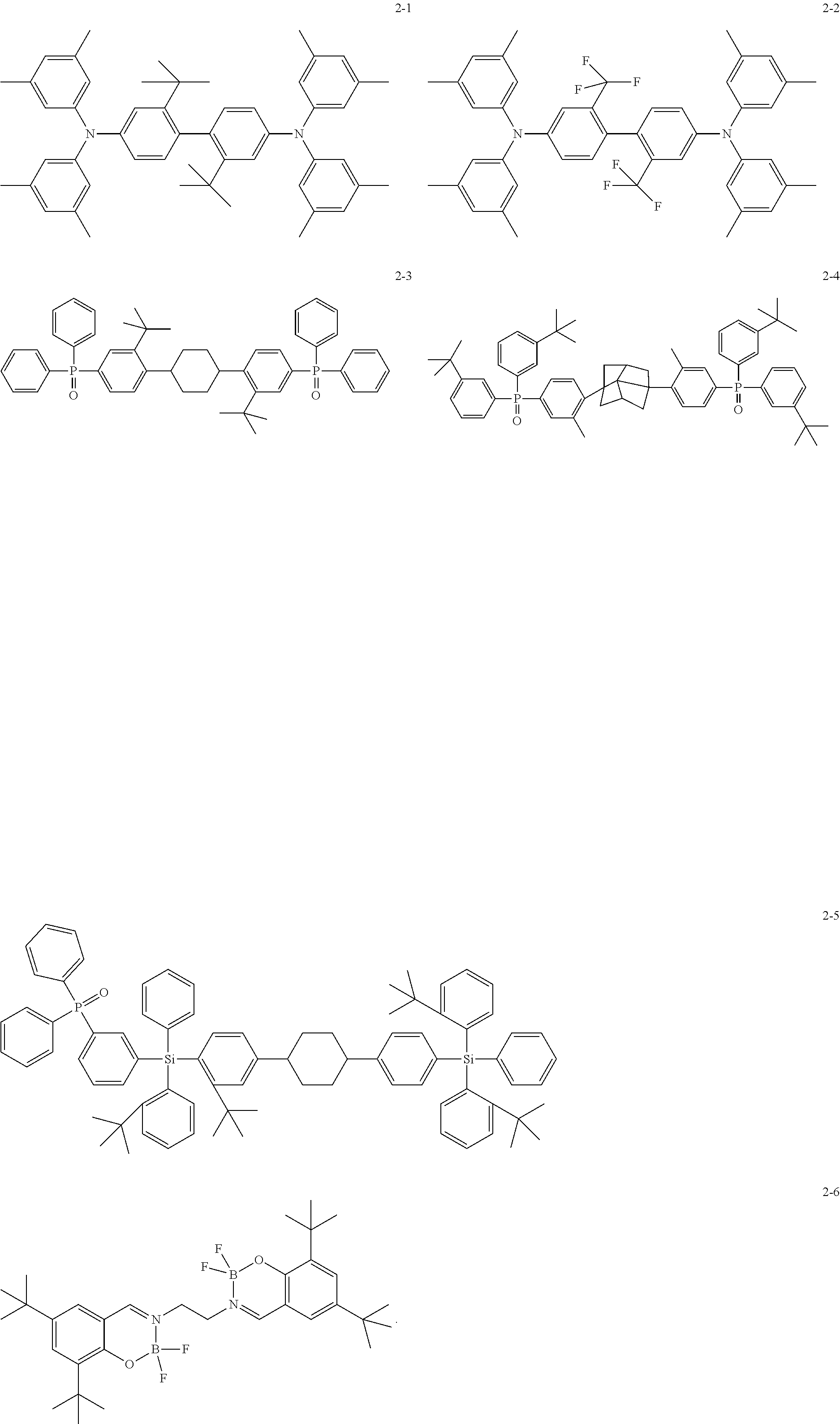

According to a second aspect of the present disclosure, there is provided a display apparatus including the organic light-emitting device as described in the first aspect.

The organic light-emitting device provided by the present disclosure includes a capping layer including a first capping layer material and a second capping layer material, the refractive index of the first capping layer material is greater than the refractive index of the second capping layer material, and the maximum absorption peak position of the first capping layer material is located between 360 nm and 400 nm. The first capping layer material covers most of the ultraviolet absorption bands, thereby helping to enhance the absorption of the capping layer to the ultraviolet region, reduce the ultraviolet light entering the device, avoid the decomposition of the guest material in the light-emitting layer, and thus improve the life of the device.

### BRIEF DESCRIPTION OF THE DRAWINGS

The above and other features and advantages of the present disclosure will become more apparent by describing exemplary embodiments thereof in detail with reference to the accompanying drawings.

FIG. 1 is a schematic structural diagram of an organic light-emitting in an exemplary embodiment of the present disclosure.

FIG. 2 is a schematic structural diagram of an organic light-emitting in another exemplary embodiment of the present disclosure.

The main elements in the drawings are as follows:

100, first electrode layer; 200, second electrode layer; 300, light-emitting functional layer; 310, hole injection layer; 321, hole transport layer; 322, electron blocking layer; 330, organic light-emitting layer; 340, hole blocking layer; 350, electron transport layer; 360, electron injection layer; 400, capping layer.

### DETAILED DESCRIPTION

Example embodiments will now be described more fully with reference to the accompanying drawings. However, the example embodiments can be implemented in various forms, and should not be construed as being limited to the embodiments set forth herein. On the contrary, these embodiments are provided so that the present disclosure will be comprehensive and complete, and fully convey the concept of the example embodiments to those skilled in the art. The described features, structures, or characteristics can be combined in one or more embodiments in any suitable manner. In the following description, many specific details are provided to provide a full understanding of the disclosed embodiments.

In the figure, the thickness of the region and layer may have been exaggerated for clarity. The same reference numerals in the figure represent the same or similar structures, therefore their detailed descriptions will be omitted.

The described features, structures, or characteristics can be combined in one or more embodiments in any suitable manner. In the following description, many specific details are provided to provide a full understanding of the embodiments of the present disclosure. However, those skilled in the art will be mean that the disclosed technical solution can be practiced without one or more of the specific details described, or other methods, components, materials, and the like may be employed. In other cases, the well-known structures, materials, or operations are not shown or described in detail to avoid blurring the main technical ideas disclosed in the present disclosure.

When a certain structure is “on” other structures, it may refer to a structure being formed as a whole on other structures, or a structure being “directly” disposed on other structures, or a structure being “indirectly” disposed on other structures through another structure.

The terms “a”, “one”, “the” are used to indicate the existence of one or more elements/components/and the like. The terms “including” and “comprising” are used to indicate open inclusion and refer to the existence of additional elements/components/and the like in addition to the listed ones. The terms “first” and “second” are only used as markers and do not limit the number of their objects.

The light-emitting layer of an OLED device includes host materials and guest material. The guest material is relatively sensitive to the ultraviolet region of ambient light. Under long-term strong light, light less than 400 nm will damage the device and easily cause a small amount of decomposition of the guest material in the light-emitting layer, thereby reducing the life of the device. In the related art, in the solution of using high-refractive index materials with lithium fluoride (LiF), some high-refractive index materials have a certain absorption in the ultraviolet region, but the absorption range covered is relatively narrow. At the same time, since LiF is an inorganic salt, it does not contribute to absorption in the ultraviolet region.

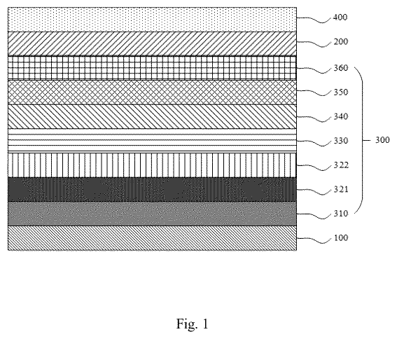

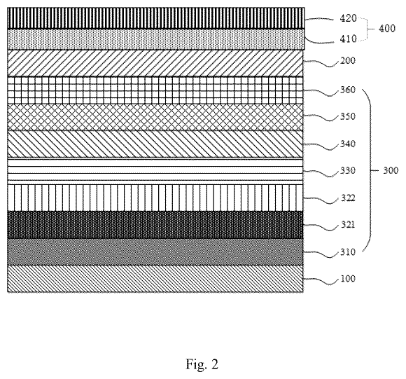

As shown in FIG. 1 and FIG. 2, the present disclosure provides an organic light-emitting device, including a first electrode layer 100, a light-emitting functional layer 300, a second electrode layer 200 and a capping layer 400 sequentially stacked, wherein the capping layer 400 includes a first capping layer material and a second capping layer material;
wherein, at the same wavelength, the refractive index of the first capping layer material is greater than the refractive index of the second capping layer material;
the maximum absorption peak position of the first capping layer material is located between 360 nm and 400 nm.

In the organic light-emitting device provided by the present disclosure, the capping layer 400 comprises a first capping layer material and a second capping layer material, the refractive index of the first capping layer material is greater than the refractive index of the second capping layer material, and the maximum absorption peak position of the first capping layer material is located between 360 nm and 400 nm. The first capping layer material covers most of the ultraviolet absorption bands, thereby helping to enhance the absorption of the capping layer to the ultraviolet region, reduce the ultraviolet light entering the device, avoid the decomposition of the guest material in the light-emitting layer, and thus improve the life of the device.

The components of the organic light-emitting device provided in the embodiment of the present disclosure are described in detail below with reference to the accompanying drawings:

As shown in FIG. 1 and FIG. 2, the organic light-emitting device provided by the present disclosure includes a first electrode layer 100, a light-emitting functional layer 300, a second electrode layer 200, and a capping layer 400 which are sequentially stacked.

The first electrode layer 100 may be used as an anode of a light-emitting device. Optionally, the anode includes the following anode material, which are preferably materials with a large work function that facilitate hole injection into the functional layer. Specific examples of the anode material include: metals such as nickel, platinum, vanadium, chromium, copper, zinc and gold or their alloys; metal oxides such as zinc oxide, indium oxide, indium tin oxide (ITO) and indium zinc oxide (IZO); combined metals and oxides such as ZnO:Al or SnO₂:Sb; or a conductive polymers such as poly(3-methylthiophene), poly[3,4-(ethylene-1,2-dioxy) thiophene] (PEDT), polypyrrole and polyaniline, but not limited thereto. Preferably, a transparent electrode includes indium tin oxide (indium tin oxide) (ITO) as an anode is included.

The second electrode layer 200 may be used as a cathode of a light-emitting device, and the cathode is preferably a material having a low work function so as to easily inject electrons into the organic light-emitting layer 330, and having good light transmittance and conductivity. Specific examples of cathode materials that may be used in the present disclosure include: metals, metal oxides, metal alloys, such as aluminium (Al), silver (Ag), gold (Au), magnesium (Mg), calcium (Ca), ytterbium (Yb), indium (In), lithium (Li), potassium (K), sodium (Na), tin (Sn), titanium (Ti), lead (Pb), samarium (Sm), yttrium (Y), indium tin oxide (ITO), magnesium-silver alloy (Mg:Ag), ytterbium-gold alloy (Yb:Au), ytterbium-silver alloy (Yb:Ag), lithium-aluminium alloy (Li:Al), lithium-calcium-magnesium alloy (Li:Ca:Al) and so on; and laminate materials, such as magnesium/aluminum (Mg/Al), magnesium/silver (Mg/Ag), aluminum/silver (Al/Ag), aluminum/gold (Al/Au), ytterbium/gold (Yb/Au), ytterbium/silver (Yb/Ag), calcium/magnesium (Ca/Mg), calcium/silver (Ca/Ag), and the like, but not limited thereto.

The light-emitting functional layer 300 may include a hole transport layer 321, an organic light-emitting layer 330 and an electron-transport layer 350 which are sequentially stacked in a direction away from the first electrode layer 100. Holes are injected into the organic light-emitting layer 330 from the anode and the hole transport layer 321, and electrons are injected into the organic light-emitting layer 330 from the cathode and the electron transport layer 350. When electrons and holes meet in the organic light-emitting layer 330, the electrons and holes recombine in the organic light-emitting layer 330 to generate excitons, and these excitons emit light while changing from an excited state to a ground state.

In some embodiments of the present disclosure, the light-emitting functional layer 300 further includes a hole injection layer 310 and an electron injection layer 360. The hole injection layer 310 is disposed between the first electrode layer 100 and the hole transport layer 321. The electron injection layer 360 is disposed between the cathode and the electron transport layer 350.

Specifically, the hole injection layer 310 may be an inorganic oxide, a molybdenum oxide, a titanium oxide, a vanadium oxide, a rhenium oxide, a ruthenium oxide, a chromium oxide, a zirconium oxide, a hafnium oxide, a tantalum oxide, a silver oxide, a tungsten oxide, a manganese oxide, or the like. It can also be a dopant of a strong electron-withdrawing system, such as F4TCNQ (2,3,5,6-tetrafluoro-7,7′,8,8′-tetracyanodimethyl-p-benzoquinone), HATCN (2,3,6,7,10,11-hexacyano-1,4,5,8,9,12-hexaazatriphenylene) and the like. The p-type doping can also be performed on the hole-transporting material, and the hole-injecting layer 310 has a thickness of 5~20 nm, and the hole injection layer 310 is formed by co-evaporation.

The hole transport layer 321 has good hole transport characteristics and can be aromatic amine or carbazole materials such as NPB (N,N′-diphenyl-N,N′-(1-naphthyl)-1,1′-biphenyl-4,4′-diamine), TPD (N,N′-diphenyl-N,N′-di(3-methylphenyl)-1,1′-biphenyl-4,4′-diamine), DFLDPBi (4,4′-bis[N-(9,9-dimethylfluorene-2-yl)-N-phenylamine]biphenyl), TCTA (tri(4-carbazole-9-ylphenyl)amine), TAPC (4,4′-cyclohexylbis[N,N-di(4-methylphenyl)aniline]) and the like.

The organic light-emitting layer 330 may be composed of a single light-emitting material, or may include a host material and a dopant material. Optionally, the organic light-emitting layer 330 is composed of a host material and a dopant material, the holes injected into the organic light-emitting layer 330 and the electrons injected into the organic light-emitting layer 330 can be compounded on the organic light-emitting layer 330 to form excitons, the excitons transfer energy to the host material, and the host material transfers energy to the dopant material so that the dopant material can emit light.

The organic light-emitting layer 330 may be a phosphorescent host and a phosphorescent dopant, and may be a fluorescent host and a fluorescent dopant. In addition, each host material may include one material, or may include more than two mixed materials.

Specifically, the host material of the blue organic light-emitting layer may be selected from anthracene derivatives ADN (9,10-di(2-naphthyl)anthracene), MADN (3-tert-butyl-9,10-di(2-naphthyl)anthracene), and the like; the dopant material can be pyrene derivatives, fluorene derivatives, perylene derivatives, styrylamine derivatives, metal complexes, etc., such as TBPe (tetrabromophenolphthalein ethyl ester potassium salt), BDAVBi (4,4″-bis[4-(diphenylamino)styryl]biphenyl), DPAVBi (4,4′-bis[4-(di-p-tolylamino)styryl]biphenyl), FIrpic (bis(4,6-difluorophenylpyridine-N,C2)picolinyliridium) and the like.

The host material of the green organic light-emitting layer may be selected from, for example, coumarin dyes, quinacridone derivatives, polycyclic aromatic hydrocarbons, diamine anthracene derivatives, carbazole derivatives, such as DMQA (N,N′-dimethylquinacridone), BA-NPB (N,N′-di-1-naphthyl-N,N′-diphenyl-[9,9′-bianthracene]-10,10′-diamine; N1,N1′-diphenyl-N1,N1′-dinaphthyl-9,9′-bianthracene-1,1′-diamine), Alq3 (8-hydroxyquinoline aluminum), CBP (4,4′-bis(N-carbazole)-1,1′-biphenyl) and the like. The dopant material can be a metal complex, such as Ir(ppy)3 (tri(2-phenylpyridine)iridium|94928-86-6), Ir(ppy)2(acac) (di(2-phenylpyridine)iridium acetylacetonate) and the like.

The host material of the red organic light-emitting layer may be selected from the group consisting of DCM series materials, such as DCJTB (2-{2-tert-butyl-6-[2-(1,1,7,7-tetramethyl-2,3,6,7-tetrahydro-1H,5H-benzo[ij]quinolizin-9-yl) vinyl]-4H-pyran-4-ylidene}malononitrile), DCJTI (2-{2-isopropyl-6-[2-(1,1,7,7-tetramethyl-2,3,6,7-tetrahydro-11H,5H-benzo[ij]quinolizin-9-yl) vinyl]-4H-pyran-4-ylidene}malononitrile), -benzo[ij]quinolizine-9-yl)vinyl]-4H-pyran-4-ylidene}malononitrile) and the like, and the dopant material can be a metal complex, such as Ir(piq)2(acac)(bis(1-phenyl-isoquinoline)(acetylacetonate)iridium(III)), PtOEP(platinum(II) octaethylporphyrin), Ir(btp)2(acac)(bis(2-(2′-benzothienyl)pyridine-N,C3′)(acetylacetonate)iridium) and the like.

The electron injection layer 360 preferably has a material capable of transporting electrons and has the effect of injecting electrons from the cathode, and has excellent film-forming ability, generally an alkali metal or metal, such as LiF, Yb, Mg, Ca or their compounds.

Furthermore, the light-emitting functional layer 300 further includes an electron blocking layer 322 and a hole blocking layer 340, the electron blocking layer 322 is disposed between the hole transport layer 321 and the organic light-emitting layer 330, and the electron blocking layer 340 is disposed between the organic light-emitting layer 330 and the electron transport layer 350.

The electron blocking layer 322 also has good hole transport characteristics, and can be a red electron blocking layer 322, a green electron blocking layer 322, or a blue electron blocking layer 322. They may be aromatic amines or carbazole materials, such as CBP (4,4′-bis(N-carbazole)-1,1′-biphenyl), PCzPA (9-phenyl-3-[4-(10-phenyl-9-anthryl)phenyl]-9h-carbazole), and the like.

The hole blocking layer 340 and the electron transport layer 350 are generally aromatic heterocyclic compounds, such as imidazole derivatives such as benzimidazole derivatives, imidazopyridine derivatives, benzimidazolephenanthridine derivatives; oxazine derivatives such as pyrimidine derivatives and triazine derivatives; compounds containing nitrogen-containing six-membered ring structures (including compounds having phosphine oxide-based substituents on the heterocyclic rings) such as quinoline derivatives, isoquinoline derivatives, phenanthroline derivatives and the like. For example: OXD-7 (2,2′-(1,3-phenyl)di[5-(4-tert-butyl phenyl)-1,3,4-oxadiazole]), TAZ (3-(biphenyl-4-yl)-5-(4-tert-butylphenyl)-4-phenyl-4H-1,2,4-triazole), p-EtTAZ (3-(4-tert-butylphenyl)-4-(4-ethylphenyl)-5-(4-biphenyl)-l,2,4-triazole), BPhen (4,7-diphenyl-l, 10-phenanthroline), TPBi (1,3,5-tris(1-phenyl-lH-benzoimidazol-2-yl)benzene) and the like.

The capping layer 400 is disposed on the side of the second electrode layer 200 away from the first electrode layer 100. The capping layer 400 includes a first capping layer material and a second capping layer material. It should be noted that the capping layer 400 can be formed by mixing the first capping layer material and the second capping layer material through a film forming process to form a capping layer 400, as shown in FIG. 1. Alternatively, the first capping layer 410 can be formed by the first capping layer material, and the second capping layer 420 can be formed by the second capping layer material, and the second capping layer 420 can be disposed on the side of the first capping layer 410 away from the first electrode layer 100, as shown in FIG. 2. The second capping layer material and the second capping layer material can improve the life of the device.

At the same wavelength, the refractive index of the first capping layer material is greater than the refractive index of the second capping layer material, that is, the first capping layer material is a high refractive index material, and the second capping layer material is a low refractive index material. In some embodiments of the present disclosure, the refractive index of the first capping layer material at a wavelength of 450 nm to 650 nm is not less than 1.9, and the refractive index of the second capping layer material at a wavelength of 450 nm to 650 nm is not greater than 1.7. Furthermore, the refractive index of the first capping layer material at a wavelength of 460 nm is greater than 2.0, and the refractive index of the second capping layer material at a wavelength of 460 nm is less than 1.7.

The maximum absorption peak position of the first capping layer material is located between 360 nm and 400 nm, covering most of the ultraviolet absorption band. Further, the second capping layer material is an organic material, and the maximum absorption peak position of the second capping layer material is located between 300 nm and 320 nm. The wavelength of ultraviolet light is less than 400 nm, and the ultraviolet light between 320 nm and 400 nm has a strong penetrating power. In the related art, it can pass through the capping layer to reach the organic light-emitting layer 330, destroying the guest material therein. In the present disclosure, the first capping layer material and the second capping layer material have maximum absorption peaks in the 360 nm~400 nm band and the 300 nm-320 nm band, respectively. Therefore, the combination of the first capping layer material and the second capping layer material can complete absorption in almost the entire band of ultraviolet light, prevent ultraviolet light from passing through the capping layer 400 to reach the organic light-emitting layer 330, protect the guest material in the organic light-emitting layer 330 from damage, and thus improve the life of the device.

Furthermore, the absorption intensity of the first capping layer material at a wavelength of 400 nm is more than 70% of the intensity at the wavelength of the maximum absorption peak position. Having a larger absorption intensity at a wavelength of 400 nm helps to improve the absorption of the entire capping layer material in the ultraviolet region. It should be noted that above or below a certain value in the present disclosure usually includes the value. For example, above 70% may include 70%, and values greater than 70%.

In addition, in order to ensure the luminous effect of the device, in some embodiments of the present disclosure, the absorption intensity of the first capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position.

The absorption intensity of the second capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position.

In visible light, light in the wavelength range of 440 nm to 480 nm is blue light, light in the wavelength range of 500 nm to 550 nm is green light, and light in the wavelength range of 600 nm to 640 nm is red light. The first capping layer material and the second capping layer material have low absorption in the blue, green and red light regions to ensure that the light emitted by the organic light emitting layer 330 can be normally transmitted through the capping layer 400 to ensure the luminous efficiency of the device.

In some embodiments of the present disclosure, the first capping layer material is selected from a monoaromatic amine or a diaromatic amine structure, and the structural formula of the first capping layer material contains at least one fused 180° plane conjugated structure, which helps to improve the refractive index of the molecules of the first capping layer material and increase the absorption of the molecules in the ultraviolet region.

Specifically, the fused 180° plane conjugated structure is selected from the group consisting of the following structures:

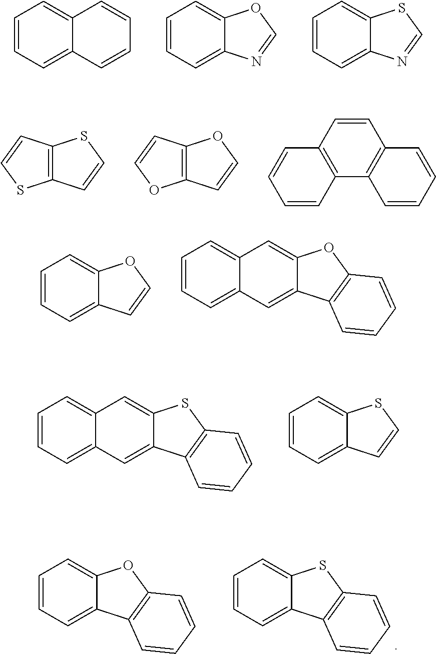

It is noted that the above conjugated structure may be located at any position in the molecular structure of the first capping material. In addition, the structure of the first capping material may include one or more of the above conjugated structures. When the structure of the first capping material includes multiple conjugated structures, the conjugated structures may be the same or different from each other.

Further, in some embodiments of the present disclosure, the structure of the first capping material is as shown in Chemical Formula 1 or Chemical Formula 2:

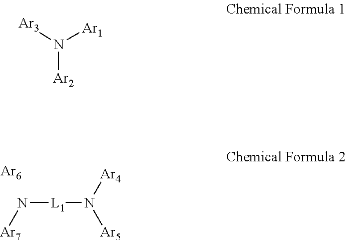

wherein, Ar₁, Ar₂, Ar₃, Ar₄, Ar₅, Ar₆, Ar₇ are each independently selected from substituted or unsubstituted aryl with 6-25 carbon atoms, substituted or unsubstituted heteroaryl with 5-25 carbon atoms, at least one of Ar₁, Ar₂, Ar₃ contains at least one fused 180° plane conjugated structure, and at least one of Ar₄, Ar₅, Ar₆, Ar₇ contains at least one fused 180° plane conjugated structure;
L₁ is selected from substituted or unsubstituted phenylene, substituted or unsubstituted biphenylene, substituted or unsubstituted naphthylene, substituted or unsubstituted fluorenylene, or a group formed by connecting any two of the above groups by a single bond;
the substituents on Ar1, Ar2, Ar3, Ar4, Ar5, Ar6, and Ar₇ are the same or different and are independently selected from aryl with 6 to 15 carbon atoms and heteroaryl with 5 to 15 carbon atoms;
the substituent on L₁ is selected from alkyl with 1 to 6 carbon atoms.

In the present disclosure, the description methods used “each . . . is independently” and “ . . . each independently selected from” can be interchanged and should be understood in a broad sense. They can mean that in different groups, the specific options expressed by the same symbols do not affect each other, or that in the same group, the specific options expressed by the same symbols do not affect each other.

In the present disclosure, the number of carbon atoms of Ar₁, Ar₂, Ar₃, Ar₄, Ar₅, Ar₆, and Ar₇ means the total number of carbon atoms. For example, Ar₁ is selected from a substituted aryl with 16 carbon atoms, and the total carbon number of the aryl and the substituents thereon is 16. For example: Ar₁ is

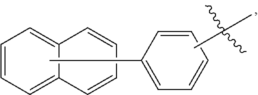

then its carbon number is 16.

In the present disclosure, when no specific definition is otherwise provided, “hetero” means including at least one heteroatom such as N, O, S, and the like in a functional group and the remaining atoms are carbon and hydrogen. The unsubstituted alkyl may be a “saturated alkyl” without any double or triple bond.

In the present disclosure, “alkyl” may include straight-chain alkyl or branched-chain alkyl. Alkyl may have 1 to 6 carbon atoms, and in the present disclosure, a numerical range such as “1 to 6” refers to each integer in the given range. For example, “1 to 6 carbon atoms” refers to an alkyl that may contain 1 carbon atom, 2 carbon atoms, 3 carbon atoms, 4 carbon atoms, 5 carbon atoms, or 6 carbon atoms. Alkyl may also be a lower alkyl having 1 to 4 carbon atoms. In addition, the alkyl may be substituted or unsubstituted.

Optionally, the alkyl is selected from the group consisting of alkyls with 1 to 6 carbon atoms, and the specific examples include, but are not limited to, methyl, ethyl, n-propyl, isopropyl, n-butyl, isobutyl, sec-butyl, tert-butyl, pentyl, and hexyl.

In the present disclosure, aryl refers to an optional functional group or substituent derived from an aromatic carbocycle. The aryl may be monocyclic aryl (e.g., phenyl) or polycyclic aryl, in other words, the aryl may be monocyclic aryl, polycyclic aryl, two or more monocyclic aryls conjugated via carbon-carbon bonds, monocyclic aryl and polycyclic aryl conjugated via carbon-carbon bond, two or more polycyclic aryls conjugated via carbon-carbon bonds. That is, unless otherwise indicated, two or more aromatic groups conjugated by carbon-carbon bonds may also be regarded as aryl of the present disclosure. The polycyclic aryls may include, for example, bicyclic fused aryls (e.g., naphthyl), tricyclic fused aryls (e.g., phenanthrenyl, fluorenyl, anthryl), and the like. The aryl does not contain hetero atoms such as B, N, O, S, P, Se and Si. For example, in the present disclosure, biphenylyl, terphenyl, and the like are aryls. Examples of aryls may include, but are not limited to, phenyl, naphthyl, fluorenyl, anthryl, phenanthrenyl, biphenyl, terphenyl, quaterphenyl, pentabiphenyl, benzo [9,10]phenanthrenyl, pyrenyl, benzofluoranthryl, chrysenyl, and the like. The “aryl” of the present disclosure may contain 6 to 25 carbon atoms, in some examples, the number of carbon atoms in the aryl may be 6 to 20, in other examples the number of carbon atoms in the aryl may be 6 to 16, and in other examples the number of carbon atoms in the aryl may be 6 to 12. For example, in the present disclosure, the number of carbon atoms in the aryl may be 6, 10, 12, 13, 14, 15, 16, 18, 20, 24 or 25, and of course, the number of carbon atoms may also be other numbers, which are not listed here one by one. In the present disclosure, biphenylyl may be understood as phenyl substituted aryl, and may also be understood as unsubstituted aryl.

In the present disclosure, arylene refers to a divalent group formed by the further loss of one hydrogen atom from the aryl.

In the present disclosure, the substituted aryl may be one or more than two hydrogen atoms in the aryl may be substituted with the group such as deuterium atom, halogen group, cyano, aryl, heteroaryl, alkyl, cycloalkyl, and the like. Specific examples of heteroaryl-substituted aryls include, but are not limited to, dibenzofuranyl-substituted phenyl, dibenzothiophene-substituted phenyl, benzoxazole-substituted phenyl, benzothiazole-substituted phenyl, thienothiophene-substituted phenyl, furofuran-substituted phenyl, benzofuran-substituted phenyl, benzothiophene-substituted phenyl, benzo[b]naphtho[2,3-d]furan-substituted phenyl, benzo[b]naphtho[2,3-d]thiophene-substituted phenyl, and the like. It should be understood that the number of carbon atoms of the substituted aryl refers to the total number of carbon atoms of the aryl and the substituent on the aryl, for example, a substituted aryl having 18 carbon atoms, refers to the total number of carbon atoms of the aryl and the substituent thereof.

In the present disclosure, specific examples of aryl as a substituent include, but are not limited to, phenyl, naphthyl, biphenyl anthracenyl, phenanthrenyl, and the like.

In the present disclosure, heteroaryl refers to a monovalent aromatic ring or derivative thereof containing at least one heteroatom in the ring, and the heteroatom may be at least one of O, N and S. The heteroaryl may be a monocyclic heteroaryl or a polycyclic heteroaryl, in other words, the heteroaryl may be a single aromatic ring system, or may be a plurality aromatic ring systems conjugated to each other via carbon-carbon bonds, and any aromatic ring system may be an aromatic monocyclic ring or an aromatic fused ring. Exemplary heteroaryls may include thienyl, furyl, pyrrolyl, imidazolyl, thiazolyl, oxazolyl, oxadiazolyl, triazolyl, pyridyl, bipyridyl, pyrimidinyl, triazinyl, acridinyl, pyridazinyl, pyrazinyl, quinolinyl, quinazolinyl, quinoxalinyl, phenoxazinyl, phthalazinyl, pyridopyrimidinyl, pyridopyrazinyl, pyrazinopyrazinyl, isoquinolinyl, indolyl, carbazolyl, benzoxazolyl, benzimidazolyl, benzothiazolyl, benzotriazolyl, benzocarbazolyl, benzothienyl, dibenzothienyl, thiophenothienyl, benzofuranyl, phenanthrolinyl, isoxazolyl, thiadiazolyl, benzothiazolyl, phenothiazinyl, silafluorenyl, dibenzofuranyl, and benzo[b]naphtho[2,3-d]furanyl, benzo[b]naphtho[2,3-d]thienyl, and the like, and not limited thereto. The “heteroaryl” of the present disclosure may contain 5 to 25 carbon atoms, in some embodiments, the number of carbon atoms in the heteroaryl may be 5 to 16, and in other embodiments, the number of carbon atoms in the aryl may be 5 to 12. For example, the number of carbon atoms can be 5, 6, 7, 10, 11, 12, 13, 18, 19, 20, 21, 22, 23, or 25. Of course, the number of carbon atoms can also be other numbers, which are not listed here.

In the present disclosure, heteroarylene involved refers to a divalent group formed by the further loss of one hydrogen atom from the heteroaryl.

In the present disclosure, the substituted heteroaryl may be one or more hydrogen atoms in the heteroaryl substituted with a group such as deuterium atom, halogen group, cyano, aryl, heteroaryl, alkyl, cycloalkyl, or the like. Specific examples of aryl-substituted heteroaryls include, but are not limited to, phenyl-substituted dibenzofuranyl, phenyl-substituted dibenzothienyl, and the like. It should be understood that the number of carbon atoms of the substituted heteroaryl refers to the total number of carbon atoms of the substituents on the heteroaryl and the heteroaryl.

In the present disclosure, specific examples of heteroaryl as a substituent include, but are not limited to benzofuranyl, benzothiophenyl, dibenzofuranyl, dibenzothiophenyl, furofuranyl, thienothiphenyl, benzo[b]naphtho[2,3-d]furanyl, benzo[b]naphtho[2,3-d]thiophenyl, benzoxazolyl, benzothiazolyl, and the like.

Furthermore, Ar₁, Ar₂, Ar₃, Ar₄, Ar₅, Ar₆, Ar₇ are each independently selected from substituted or unsubstituted phenyl, substituted or unsubstituted biphenyl, substituted or unsubstituted naphthyl, substituted or unsubstituted anthracenyl, substituted or unsubstituted phenanthryl, substituted or unsubstituted benzo[b]naphtho[2,3-d]furanyl, substituted or unsubstituted benzo[b]naphtho[2,3-d]thienyl, substituted or unsubstituted dibenzofuranyl, substituted or unsubstituted dibenzothienyl, substituted or unsubstituted benzofuranyl, substituted or unsubstituted benzothienyl, substituted or unsubstituted benzoxazolyl, substituted or unsubstituted benzothiazolyl, substituted or unsubstituted thienothiphenyl, substituted or unsubstituted furanofuranyl.

The substituents on Ar₁, Ar₂, Ar₃, Ar₄, Ar₅, Ar₆, and Ar₇ are the same or different from each other, and are each independently selected from phenyl, naphthyl, anthracenyl, phenanthryl, benzo[b]naphtho[2,3-d]furanyl, benzo[b]naphtho[2,3-d]thienyl, dibenzofuranyl, dibenzothienyl, benzofuranyl, benzothienyl, benzoxazolyl, benzothiazolyl, thienothiphenyl, and furofuranyl.

In some embodiments of the present disclosure, the fused 180° plane conjugated structure is selected from the group consisting of the following structures:

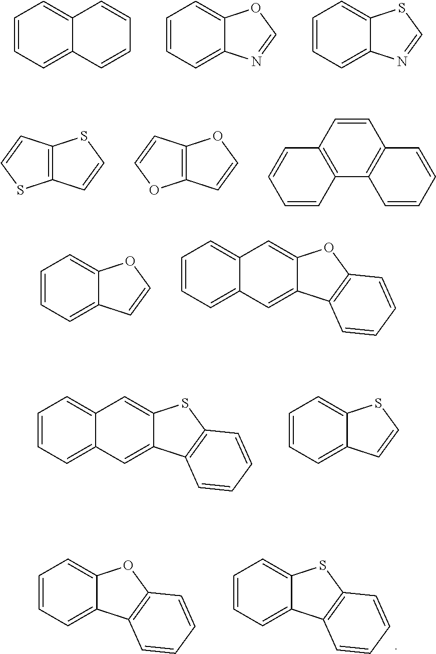

Furthermore, Ar₁, Ar₂, Ar₃, Ar₄, Ar₅, Ar₆, Ar₇ are each independently selected from the group consisting of the following groups:

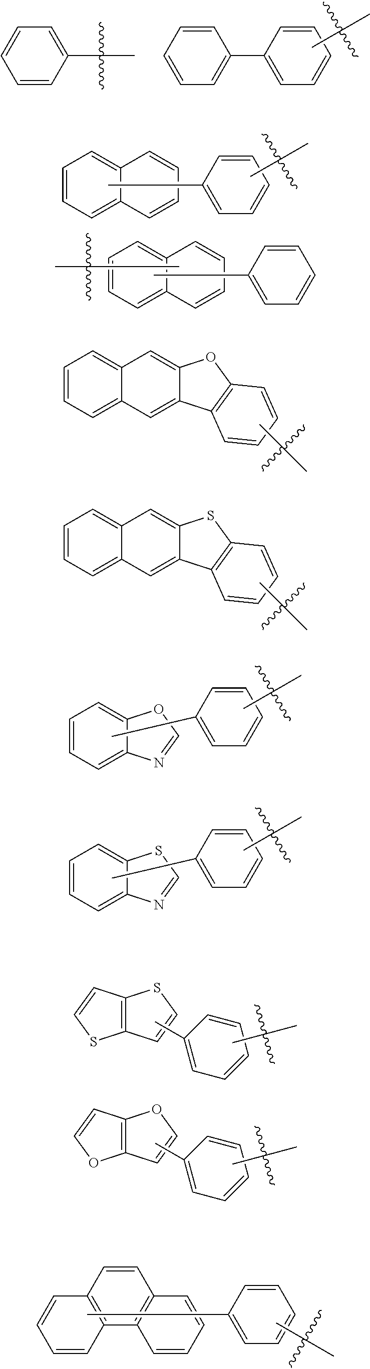

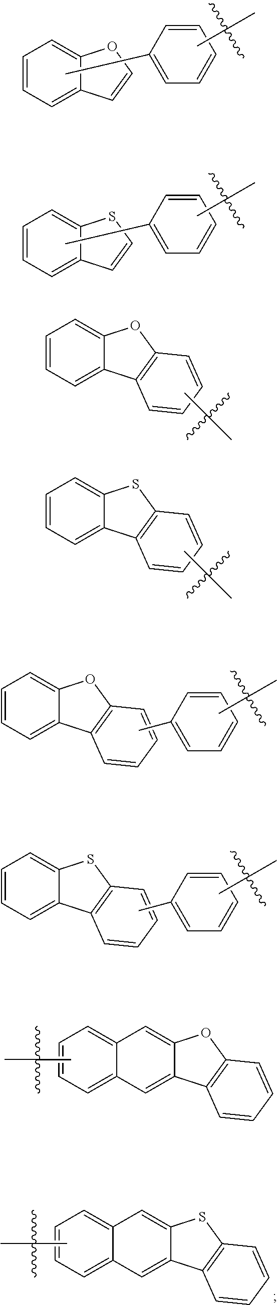

wherein, represents a chemical bond.

In the present disclosure, the non-positional connecting bond refers to the single bond

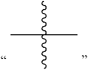

extending from a ring system, which means that one end of the connecting bond can be connected to any position in the ring system it passes, and the other end is connected to the rest of the compound molecule.

For example, as shown in the following formula (g), the benzoxazolyl represented by formula (g) is connected to other positions of the molecule through the non-positional connecting bond that passes the benzene ring and the oxazole ring, and its meaning includes any possible connection method shown in formulas (g-1) to (g-5).

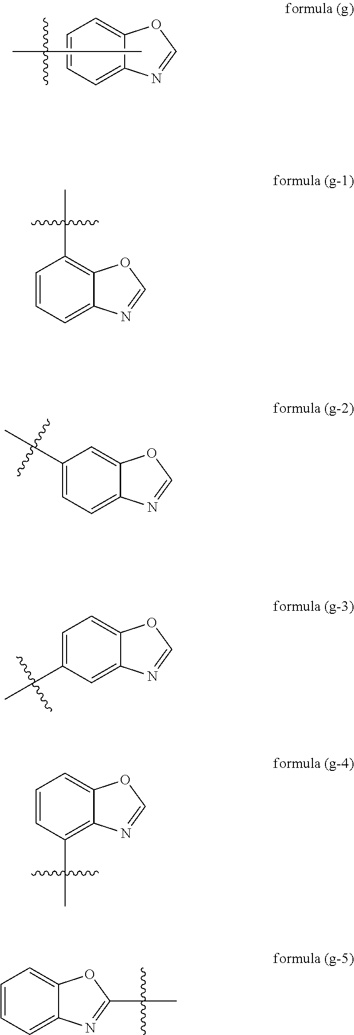

The non-positional substituent in the present disclosure refers to the substituent connected by a single bond extending from the center of the ring system, which means that the substituent may be connected to any possible position in the ring system. For example, in the following formula (h), the substituent R1 represented by the formula (h) is connected to the benzene ring through a non-positional connecting bond, and its meaning includes any possible connection method shown in formulas (h-1) to the formula (h-5).

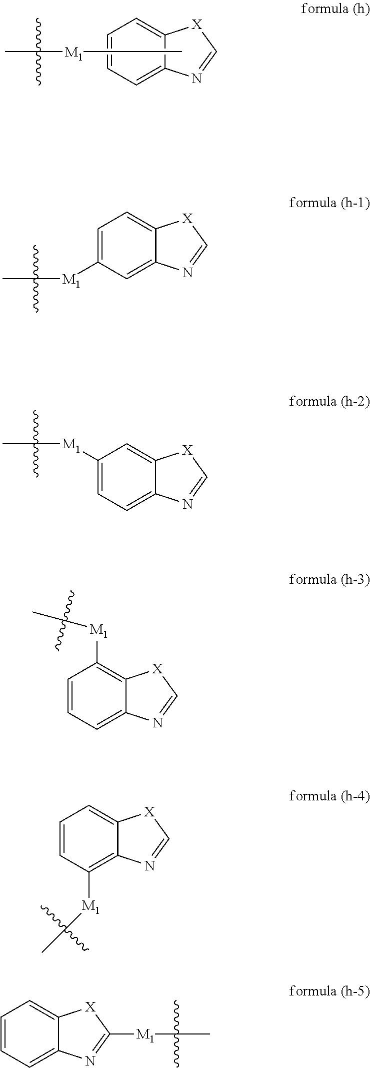

In some embodiments, the first capping layer material is selected from the following structural composition group:

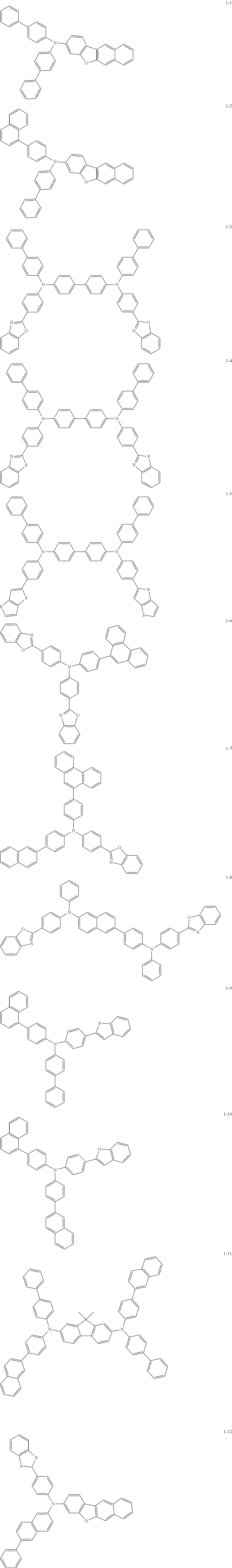

In some embodiments of the present disclosure, the structure of the second capping layer material does not include a fused 180° planes conjugated structure;
the second capping layer material has a structure containing at least three R groups, and the R groups are substituted or unsubstituted alkyl with 1 to 6 carbon atoms or silane groups;
the substituents on the substituted alkyl or silane groups are the same as or different from each other and are independently selected from fluorine and an alkyl group having 1 to 4 carbon atoms.

In this type of embodiment, containing at least three substituted or unsubstituted alkyl or silane groups helps to increase the volume of the second capping layer material molecule, reduce conjugation, and further reduce the refractive index of the molecule. The multiple R groups can be the same or different.

Specifically in some embodiments, the R group is selected from methyl, tert-butyl, trimethylsilyl, and fluoromethyl. The structure of the second capping layer material may contain one, two, or more of these groups, but the number of these groups contained is at least three. For example, the structure of the second capping layer material may contain three methyl, three tert-butyl, or three trimethylsilyl. Alternatively, the structure of the second capping layer material contains two tert-butyl groups and two methyl groups, and the like.

In some embodiments, the second capping layer material is selected from the group consisting of:

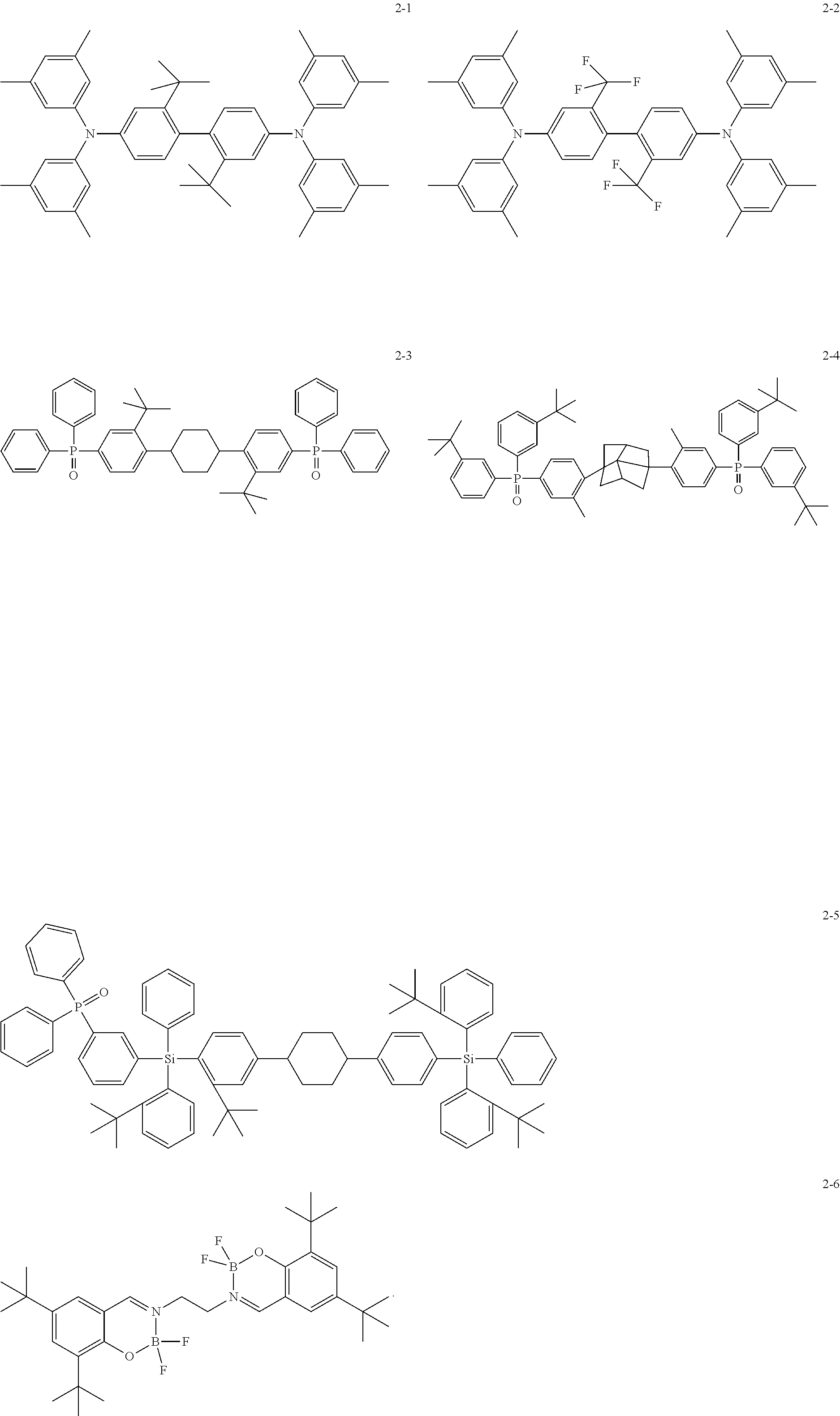

The present disclosure also provides a display device, including the above-mentioned organic light-emitting device. The display device can be an electronic device such as a mobile phone, a tablet computer, a television, etc., which are not listed one by one here.

### Device Embodiment

Comparative Example 1 Preparation process: The prepared ITO substrate was cleaned and dried; the hole injection layer HIL, material (m-MTDATA: F4TCNQ), the hole transport layer HTL material (m-MTDATA), and the electron blocking layer EBL material (CBP) were sequentially deposited on the anode; then the organic light-emitting layer material (BH:BD) was evaporated; the electron blocking layer HBL material (TPBI), the electron transport layer ETL material (BCP:Liq), and the electron injection layer EIL, material (Yb) were evaporated on the organic light-emitting layer; then the cathode (Mg:Ag) was evaporated. On the cathode, the first capping layer material (CP1) with a high refractive index was evaporated; on the first capping layer, the second capping layer material (LiF) was evaporated as the second capping layer. The device structure is:
ITO/m-MTDATA: F4TCNQ 3% 10 nm/m-MTDATA 100 nm/CBP 10 nm/BH:BD 5% 20 nm/TPBI 5 nm/BCP:Liq 1:1 30 nm/Yb 1 nm/Mg:Ag 13 nm/CP1 80 nm/LiF 60 nm.

### Example 1-24 Preparation Process

The first capping layer material and the second capping layer material in Comparative Example 1 are replaced with reference to the data in Table 2, and the rest remain unchanged.

The material structures in the device examples are shown in Table 1.

TABLE 1

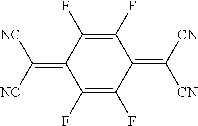 [SMILES: N#CC(C#N)=c1c(F)c(F)c(=C(C#N)C#N)c(F)c1F]

R4TCNQ

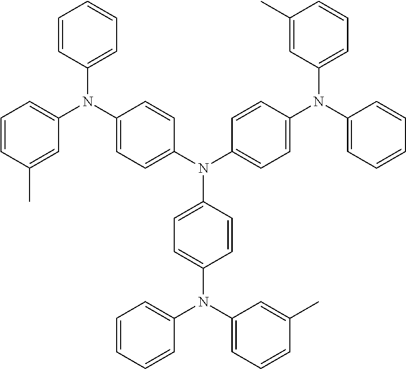 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1]

m-MTDATA

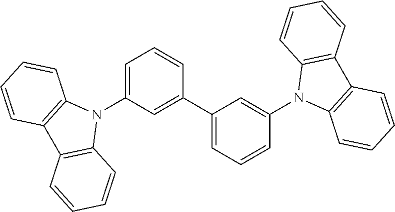 [SMILES: c1cc(-c2cccc(-n3c4ccccc4c4ccccc43)c2)cc(-n2c3ccccc3c3ccccc32)c1]

CBP

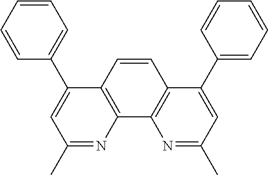 [SMILES: Cc1cc(-c2ccccc2)c2ccc3c(-c4ccccc4)cc(C)nc3c2n1]

BCP

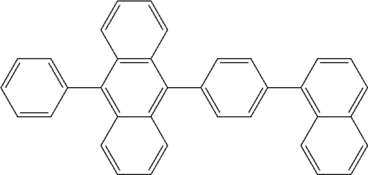 [SMILES: c1ccc(-c2c3ccccc3c(-c3ccc(-c4cccc5ccccc45)cc3)c3ccccc23)cc1]

BH

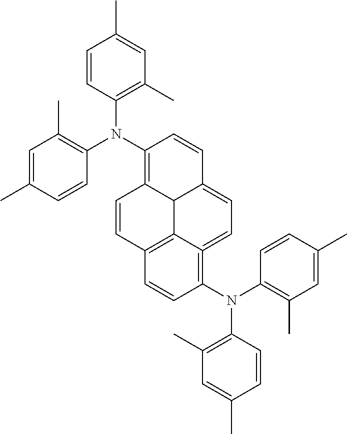

BD

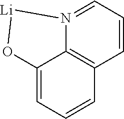

Liq

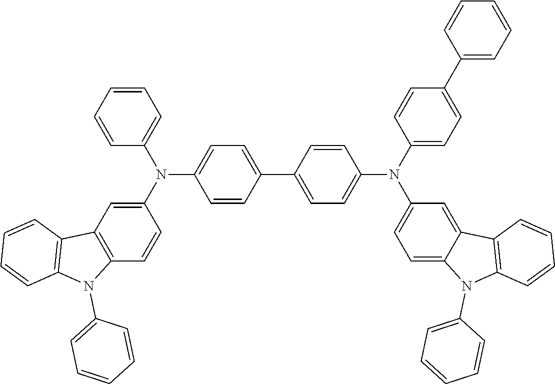 [SMILES: c1ccc(-c2ccc(N(c3ccc(-c4ccc(N(c5ccccc5)c5ccc6c(c5)c5ccccc5n6-c5ccccc5)cc4)cc3)c3ccc4c(c3)c3ccccc3n4-c3ccccc3)cc2)cc1]

CP1

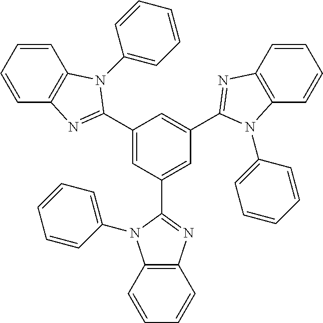 [SMILES: c1ccc(-n2c(-c3cc(-c4nc5ccccc5n4-c4ccccc4)cc(-c4nc5ccccc5n4-c4ccccc4)c3)nc3ccccc32)cc1]

TPBI

The performance of the organic light-emitting device prepared as above was analyzed under the condition of 20 mA/cm², and the results are shown in Table 2:

TABLE 2

| | CPL | | | | |
|---|---|---|---|---|---|
| | The first | The second | | | |
| | capping | capping | | | |
| | layer | layer | | | Life |
| | material | material | Voltage | EQE | (LT95@1000 nit) |
| Comparative | CP1 | LIF | 100% | 100% | 100% |
| Example 1 | | | | | |
| Example 1 | Compound 1-1 | LiF | 99% | 104% | 108% |
| Example 2 | Compound 1-2 | | 100% | 106% | 110% |
| Example 3 | Compound 1-4 | | 98% | 102% | 103% |
| Example 4 | Compound 1-6 | | 99% | 104% | 106% |
| Example 5 | Compound 1-8 | | 100% | 103% | 104% |
| Example 6 | Compound 1-12 | | 98% | 107% | 106% |
| Example 7 | Compound 1-1 | Compound 2-1 | 98% | 105% | 109% |
| Example 8 | Compound 1-2 | | 100% | 106% | 112% |
| Example 9 | Compound 1-4 | | 99% | 103% | 105% |
| Example 10 | Compound 1-6 | | 98% | 106% | 107% |
| Example 11 | Compound 1-8 | | 100% | 105% | 105% |
| Example 12 | Compound 1-12 | | 98% | 108% | 108% |
| Example 13 | Compound 1-1 | Compound 2-2 | 98% | 107% | 110% |
| Example 14 | Compound 1-2 | | 99% | 109% | 114% |
| Example 15 | Compound 1-4 | | 98% | 105% | 107% |
| Example 16 | Compound 1-6 | | 98% | 109% | 110% |
| Example 17 | Compound 1-8 | | 100% | 106% | 107% |
| Example 18 | Compound 1-12 | | 98% | 110% | 112% |
| Example 19 | Compound 1-1 | Compound 2-4 | 97% | 108% | 111% |
| Example 20 | Compound 1-2 | | 98% | 111% | 116% |
| Example 21 | Compound 1-4 | | 98% | 107% | 109% |
| Example 22 | Compound 1-6 | | 98% | 111% | 111% |
| Example 23 | Compound 1-8 | | 99% | 108% | 108% |
| Example 24 | Compound 1-12 | | 98% | 112% | 115% |

The values in Table 2 are based on Comparative Example 1, and the percentages of the Examples relative to the Comparative Example. Compared with the light-emitting device prepared in Comparative Example 1, the CPLs of Examples 1-24 using the first capping layer material and the second capping layer material of the present disclosure have higher light extraction efficiency, better stability, and improved efficiency and life.

Comparing Examples 1 to 6 with Examples 7 to 8, Examples 13 to 18, and Examples 19 to 24 respectively, it can be seen that when the material of the second capping layer is an organic material, the life of the device is improved more effectively.

It should be understood that the present disclosure does not limit its application to the detailed structure and arrangement of the components set forth in this specification. The present disclosure can have other embodiments, and can be implemented and executed in a variety of ways. The foregoing variations and modifications fall within the scope of the present disclosure. It should be understood that the present disclosure as disclosed and defined herein extends to all alternative combinations of two or more individual features mentioned or apparent in the text and/or the accompanying drawings. All these different combinations constitute a number of alternative aspects of the present disclosure. Embodiments of this specification illustrate the best modes known for carrying out the present disclosure and will enable those skilled in the art to make use of the present disclosure.

1. An organic light-emitting device, comprising a first electrode layer, a light-emitting functional layer, a second electrode layer and a capping layer sequentially stacked, wherein the capping layer includes a first capping layer material and a second capping layer material;
wherein, at the same wavelength, the refractive index of the first capping layer material is greater than the refractive index of the second capping layer material;
the maximum absorption peak position of the first capping layer material is located between 360 nm and 400 nm.

2. The organic light-emitting device according to claim 1, wherein the second capping layer material is an organic material, and the maximum absorption peak position of the second capping layer material is located between 300 nm and 320 nm.

3. The organic light-emitting device according to claim 1, wherein the absorption intensity of the first capping layer material at a wavelength of 400 nm is more than 70% of the intensity at the wavelength of the maximum absorption peak position.

4. The organic light-emitting device according to claim 2, wherein the absorption intensity of the first capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position;
the absorption intensity of the second capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position.

5. The organic light-emitting device according to claim 1, wherein the first capping layer material is selected from a monoaromatic amine or a diaromatic amine structure, and the structural formula of the first capping layer material contains at least one fused 180° plane conjugated structure.

6. The organic light-emitting device according to claim 5, wherein the fused 180° plane conjugated structure is selected from the group consisting of the following structures:

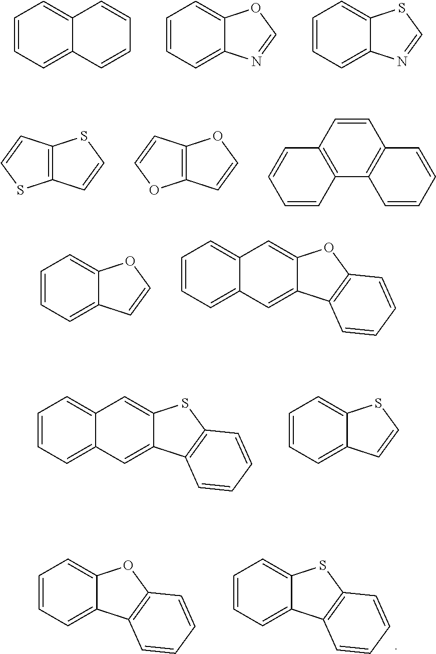

7. The organic light-emitting device according to claim 1, wherein the structure of the first capping layer material is as shown in Chemical Formula 1 or Chemical Formula 2: 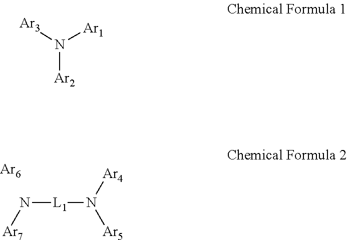
wherein, Ar₁, Ar₂, Ar₃, Ar₄, Ar₅, Ar₆, Ar₇ are each independently selected from substituted or unsubstituted aryl with 6-25 carbon atoms, substituted or unsubstituted heteroaryl with 5-25 carbon atoms, at least one of Ar₁, Ar₂, Ar₃ contains at least one fused 180° plane conjugated structure, and at least one of Ar₄, Ar₅, Ar₆, Ar₇ contains at least one fused 180° plane conjugated structure;
L₁ is selected from substituted or unsubstituted phenylene, substituted or unsubstituted biphenylene, substituted or unsubstituted naphthylene, substituted or unsubstituted fluorenylene, or a group formed by connecting any two of the above groups by a single bond;
the substituents on Ar₁, Ar₂, Ar₃, Ar₄, Ar₅, Ar₆, and Ar₇ are the same or different and are independently selected from aryl with 6 to 15 carbon atoms and heteroaryl with 5 to 15 carbon atoms;
the substituent on L₁ is selected from alkyl with 1 to 6 carbon atoms.

8. The organic light-emitting device according to claim 7, wherein the fused 180° plane conjugated structure is selected from the group consisting of the following structures:

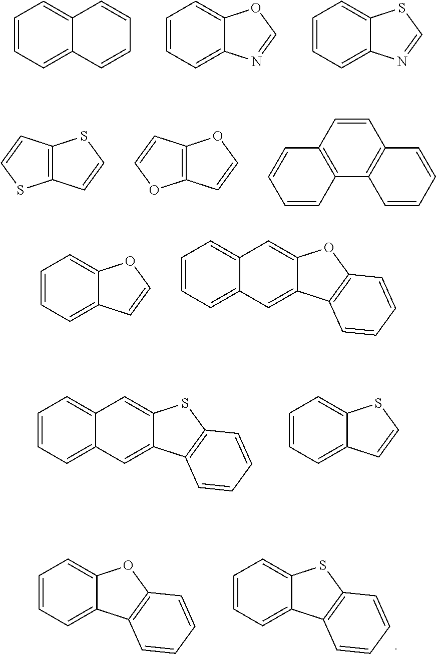

9. The organic light-emitting device according to claim 7, wherein Ar₁, Ar₂, Ar₃, Ar₄, Ar₅, Ar₆, Ar₇ are each independently selected from the group consisting of the following groups: 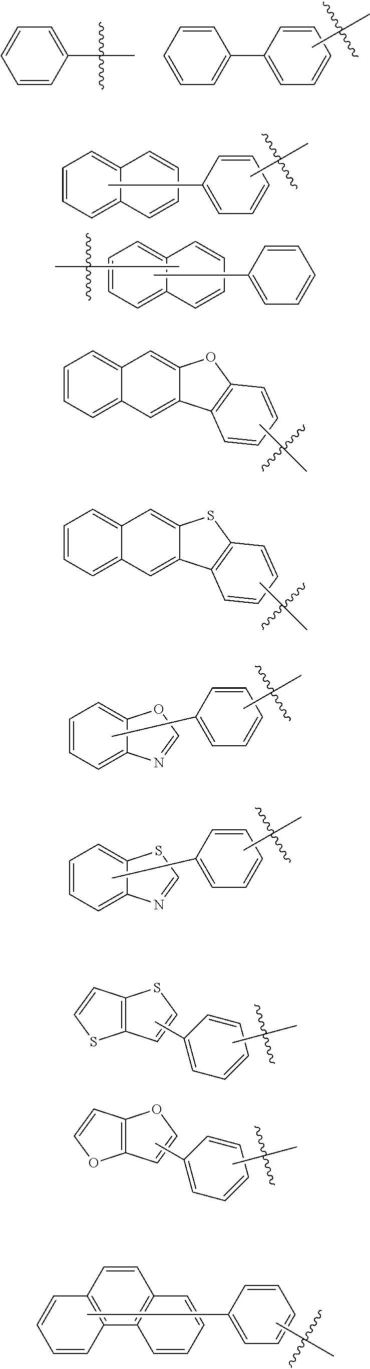 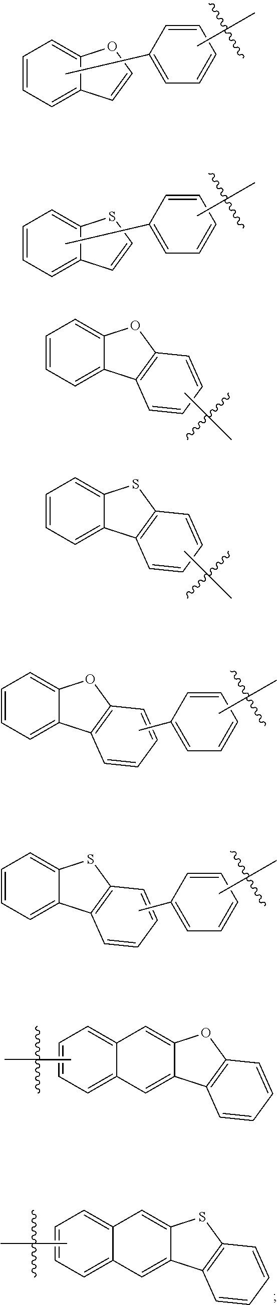
wherein, 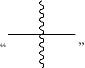
represents a chemical bond.

10. The organic light-emitting device according to claim 2, wherein the structure of the second capping layer material does not include a fused 180° plane conjugated structure;
the second capping layer material has a structure containing at least three R groups, and the R group is substituted or unsubstituted alkyl with 1 to 6 carbon atoms or silane group;
the substituents on the substituted alkyl or silane groups are the same as or different from each other and are independently selected from fluorine or an alkyl with 1 to 4 carbon atoms.

11. The organic light-emitting device according to claim 2, wherein the structure of the second capping layer material does not include a fused 180° plane conjugated structure;
the structure of the second capping layer material includes a non-conjugated structure, and the non-conjugated structure is selected from the group consisting of the following structures:

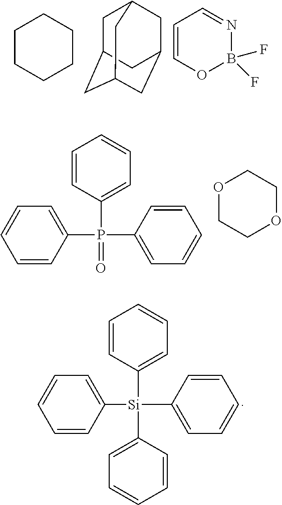

12. The organic light-emitting device according to claim 10, wherein the structure of the second capping layer material includes at least three R groups, and the R groups are selected from methyl, tert-butyl, trimethylsilyl, and fluoromethyl.

13. The organic light-emitting device according to claim 1, wherein the capping layer includes a first capping layer and a second capping layer stacked in a direction away from the first electrode layer, the first capping layer includes the first capping layer material, and the second capping layer includes the second capping layer material.

14. The organic light-emitting device according to claim 1, wherein the refractive index of the first capping layer material at a wavelength of 450 nm to 650 nm is not less than 1.9, and the refractive index of the second capping layer material at a wavelength of 450 nm to 650 nm is not greater than 1.7.

15. The organic light-emitting device according to claim 1, wherein the first capping layer material is selected from the following structural composition group:

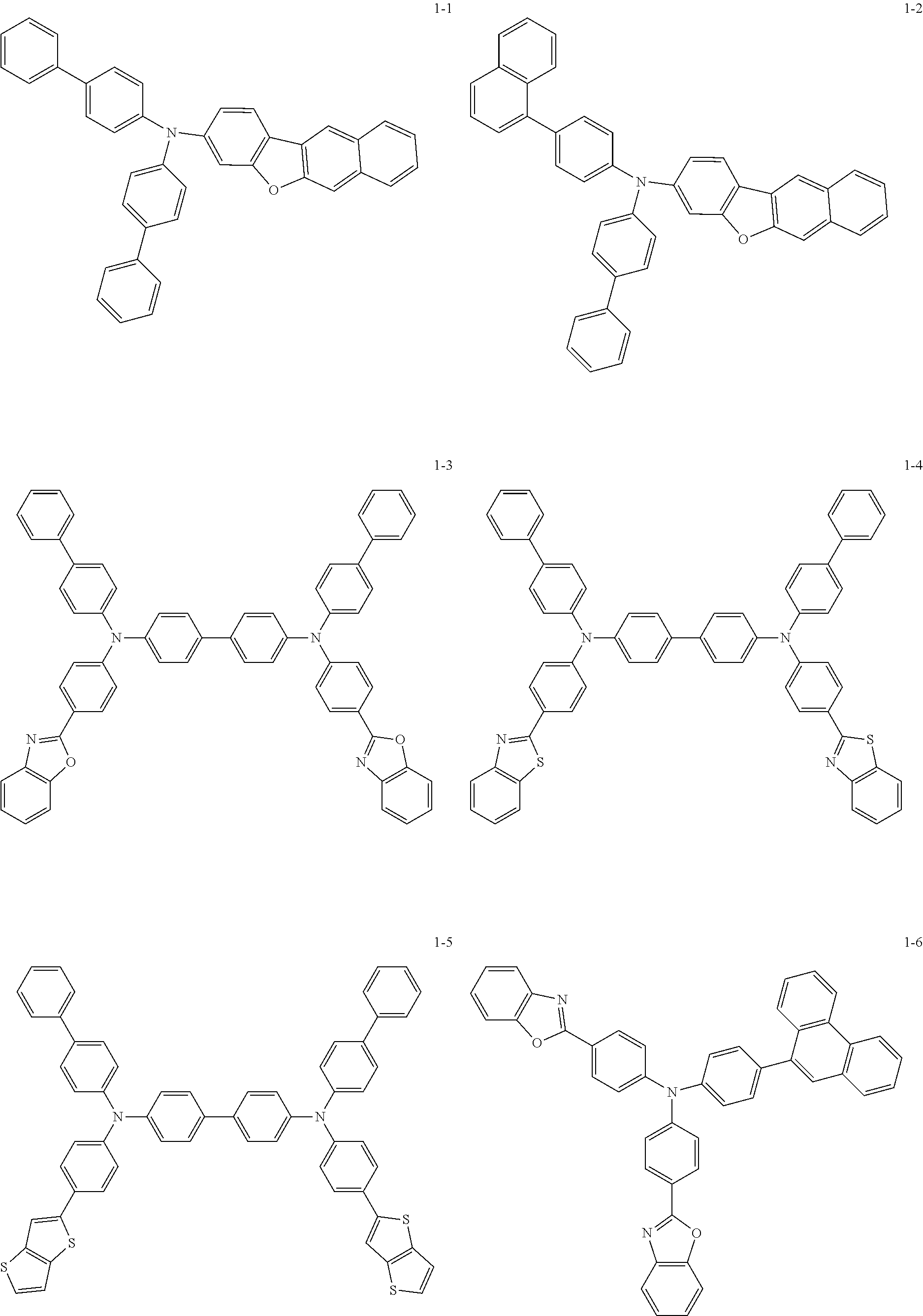

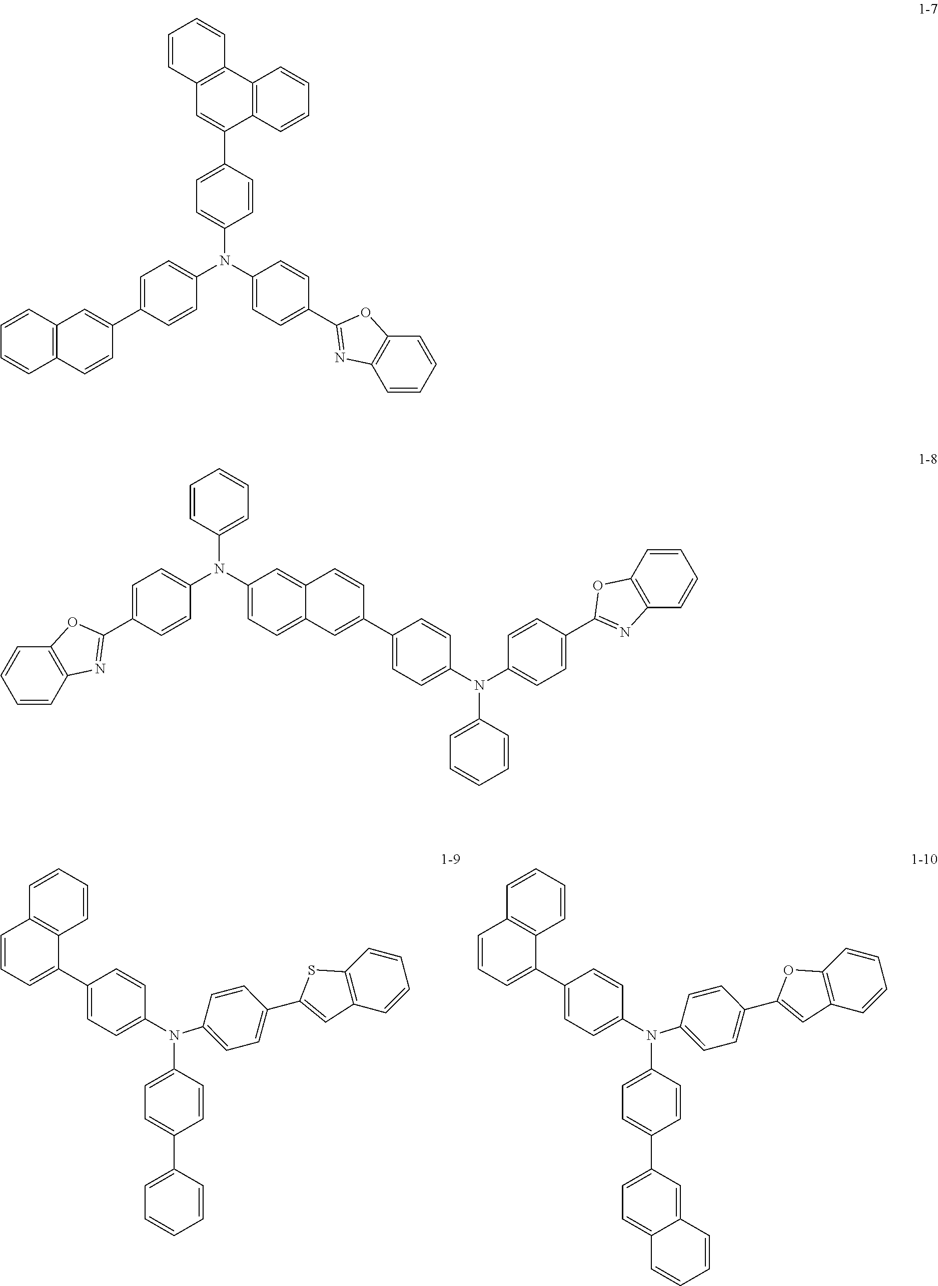 [SMILES: c1ccc2cc(-c3ccc(N(c4ccc(-c5nc6ccccc6o5)cc4)c4ccc(-c5cc6ccccc6c6ccccc56)cc4)cc3)ccc2c1 ; c1ccc(N(c2ccc(-c3ccc4cc(N(c5ccccc5)c5ccc(-c6nc7ccccc7o6)cc5)ccc4c3)cc2)c2ccc(-c3nc4ccccc4o3)cc2)cc1 ; c1ccc(-c2ccc(N(c3ccc(-c4cc5ccccc5s4)cc3)c3ccc(-c4cccc5ccccc45)cc3)cc2)cc1 ; c1ccc2cc(-c3ccc(N(c4ccc(-c5cc6ccccc6o5)cc4)c4ccc(-c5cccc6ccccc56)cc4)cc3)ccc2c1]

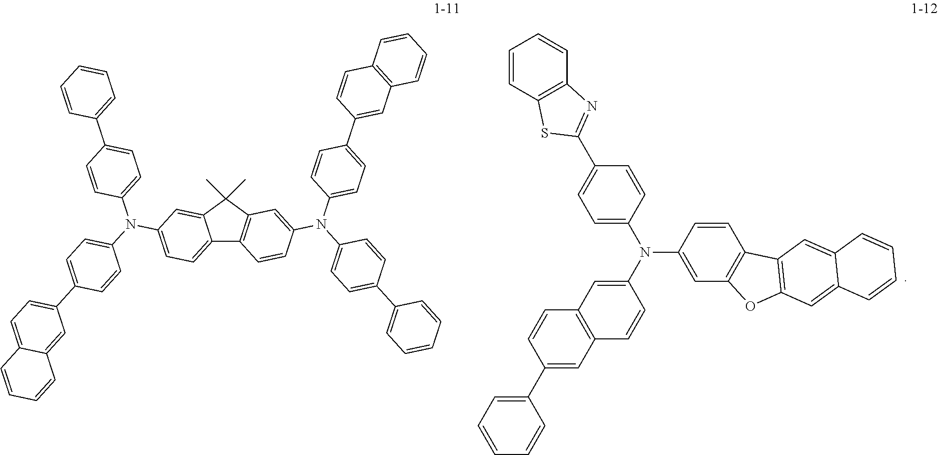 [SMILES: CC1(C)c2cc(N(c3ccc(-c4ccccc4)cc3)c3ccc(-c4ccc5ccccc5c4)cc3)ccc2-c2ccc(N(c3ccc(-c4ccccc4)cc3)c3ccc(-c4ccc5ccccc5c4)cc3)cc21 ; c1ccc(-c2ccc3cc(N(c4ccc(-c5nc6ccccc6s5)cc4)c4ccc5c(c4)oc4cc6ccccc6cc45)ccc3c2)cc1]

16. The organic light-emitting device according to claim 1, wherein the second capping layer material is selected from the group consisting of the following structures:

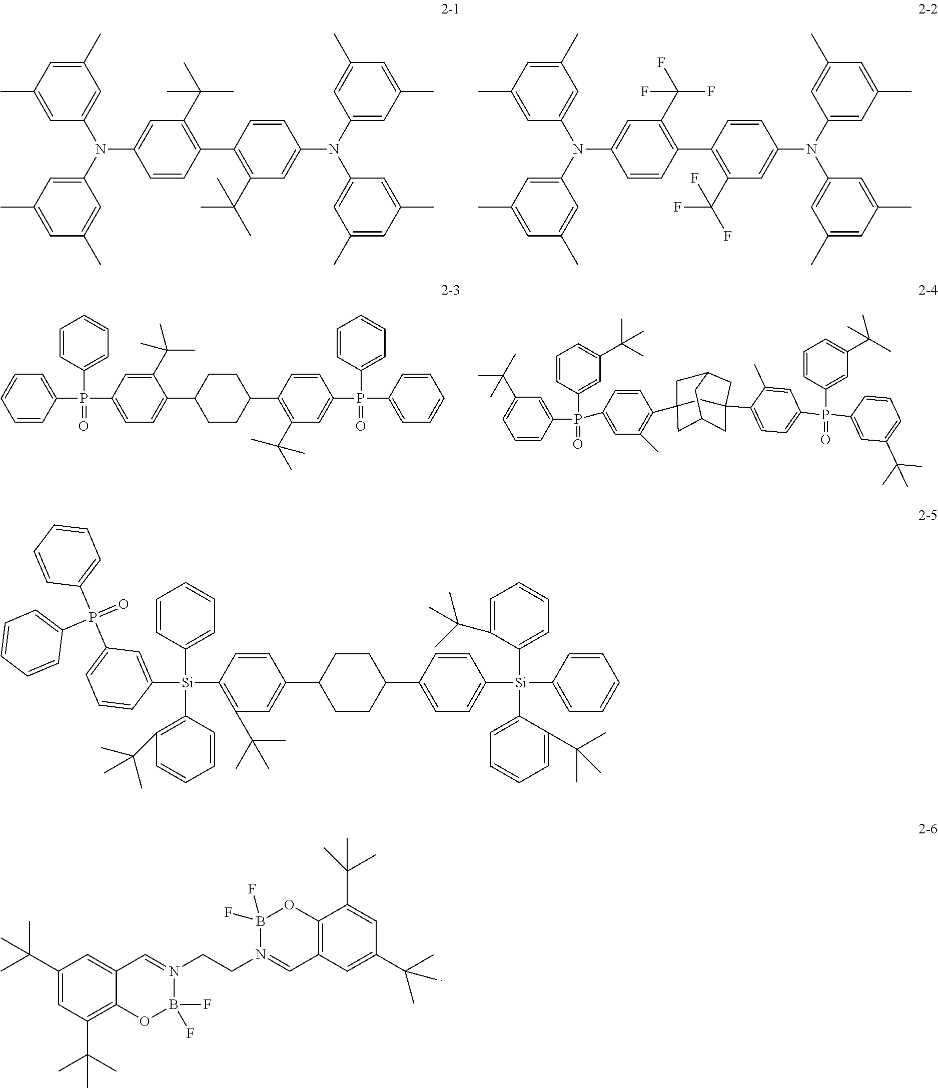

17. A display apparatus, comprising the organic light-emitting device;
wherein the organic light-emitting device comprises a first electrode layer, a light-emitting functional layer, a second electrode layer and a capping layer sequentially stacked, wherein the capping layer includes a first capping layer material and a second capping layer material;
wherein, at the same wavelength, the refractive index of the first capping layer material is greater than the refractive index of the second capping layer material;
the maximum absorption peak position of the first capping layer material is located between 360 nm and 400 nm.

18. The display apparatus according to claim 17, wherein the second capping layer material is an organic material, and the maximum absorption peak position of the second capping layer material is located between 300 nm and 320 nm.

19. The display apparatus according to claim 17, wherein the absorption intensity of the first capping layer material at a wavelength of 400 nm is more than 70% of the intensity at the wavelength of the maximum absorption peak position.

20. The display apparatus according to claim 19, wherein, wherein the absorption intensity of the first capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position;
the absorption intensity of the second capping layer material at a wavelength of 450 nm is less than 20% of the intensity at the wavelength of the maximum absorption peak position, and the absorption intensities at wavelengths of 530 nm and 620 nm are less than 1% of the intensity at the wavelength of the maximum absorption peak position.
